(19) United States
(12) Patent Application Publication
(10) Pub. No.: US 2022/0344561 A1
(43) Pub. Date: Oct. 27, 2022

(54) Thermal detector

(71) Applicant: Teknologian tutkimuskeskus VTT Oy, Espoo (FI)

(72) Inventors: Aapo Varpula, Espoo (FI); Jonna Tiira, Espoo (FI); Kirsi Tappura, Espoo (FI); Grigoras Kestutis, Espoo (FI); Mika Prunnila, Espoo (FI)

(21) Appl. No.: 17/760,829

(22) PCT Filed: Sep. 11, 2020
(86) PCT No.: PCT/FI2020/050582

§ 371 Date: Mar. 16, 2022

(30) Foreign Application Priority Data
Sep. 16, 2019 (FI) 20195772

(51) Int. Cl. H01L 35/32; G01J 5/02; G01J 5/12; H01L 35/34

(52) U.S. Cl. CPC H01L 35/32; G01J 5/023; G01J 5/12; H01L 35/34; G01J 5/024

(57) ABSTRACT

According to an example aspect of the present invention, there is provided a detector comprising an optically absorbing membrane suspended over a cavity between the membrane and a substrate, the substrate comprised in the detector, and a thermoelectric transducer attaching the optically absorbing membrane over the cavity, wherein the optically absorbing membrane forms a contacting element between n-type and p-type thermoelectric elements of the thermoelectric transducer.

### FIELD

The present disclosure relates to thermoelectric thermal detectors.

### BACKGROUND

Optical detectors are light-sensitive sensors, which determine presence and/or intensity of incident electromagnetic radiation and output a measured value in terms of a suitable electrical signal. Optical detectors are split into quantum-type and thermal-type detectors. Quantum detectors, or photovoltaic and photoconductive detectors, are typically faster, and have often higher sensitivity than thermal detectors but are relatively complex. Quantum detectors operating in the infrared range are often made of expensive and/or toxic materials, and need to be operated at low temperatures to achieve high sensitivity (due to suppression of noise by reduced temperature). The thermal-type sensors are devices configured to determine a power of electromagnetic radiation by converting it into heat, and determining the generated temperature in terms of a suitable electrical signal.

Thermal sensors utilize various technologies, but the most relevant commercial technologies are resistive and thermoelectric thermal detectors. A thermal detector consists of an absorber of incident radiation and a transducer, which converts the change of the temperature of the absorber into an electric signal. A resistive thermal detector, sometimes referred to as a bolometer, uses temperature dependent resistors as transducers. A thermoelectric thermal detector, often a thermopile or a thermocouple, uses thermoelectric transduction based on the thermoelectric effect.

### SUMMARY

According to some aspects, there is provided the subject-matter of the independent claims. Some embodiments are defined in the dependent claims.

According to a first aspect of the present disclosure, there is provided a detector comprising an optically absorbing membrane suspended over a cavity between the membrane and a substrate, the substrate comprised in the detector, and a thermoelectric transducer attaching the optically absorbing membrane over the cavity, wherein the optically absorbing membrane forms a contacting element between n-type and p-type thermoelectric elements of the thermoelectric transducer.

According to a second aspect of the present disclosure, there is provided a method of manufacturing a detector, comprising obtaining a substrate wafer and depositing an oxide layer on the substrate wafer, depositing a thermoelectric transducer layer on the oxide layer, depositing an optically absorbing layer on the oxide layer or on the thermoelectric transducer layer, and etching a recess into the oxide layer to form a cavity, leaving an optically absorbing membrane comprising the optically absorbing layer and part of the thermoelectric transducer layer suspended over the cavity by the thermoelectric transducer layer.

### BRIEF DESCRIPTION OF THE DRAWINGS

FIG. 1A illustrates an example thermal detector in accordance with at least some embodiments of the present invention;

FIG. 1B illustrates an example thermal detector in accordance with at least some embodiments of the present invention;

FIG. 2A illustrates an example thermal detector in accordance with at least some embodiments of the present invention;

FIG. 2B illustrates an example thermal detector with patterned membrane in accordance with at least some embodiments of the present invention;

FIG. 3A illustrates examples of device configurations;

FIG. 3B illustrates examples of device configurations;

FIGS. 4A-4D illustrates phases of a manufacturing method;

FIGS. 5A-5D illustrates variant absorbing membrane structures, and

FIG. 6 is a flow graph of a method in accordance with at least some embodiments of the present invention.

### EMBODIMENTS

A detector constructed as disclosed herein comprises an optically absorbing membrane suspended by a thermoelectric transducer, for example over a cavity. The cavity may have a reflector at its bottom to reflect back the fraction of incident light the membrane did not absorb, to enhance sensitivity of the detector. The cavity may have a resonant function. The membrane may be a nanomembrane, its thickness being in the nanometre scale. The nanoscale membrane is light-weight, enabling it to warm up faster as a response to incident radiation, which enhances a response speed of the detector. The disclosed detector further does not have a separate support structure, as the membrane is directly suspended and attached over the cavity by the thermoelectric transducer itself. The fact the detector has no separate support structure also enhances response time, as in systems with support structures the support structure slows down the response time by increasing the heat capacity of the detector. Beneficially, the herein disclosed detector may be manufactured using safer (e.g. less toxic) materials. Such materials may also be cheaper. Further, the herein disclosed detector may be manufactured using microelectromechanical, MEMS, methods.

Quantum detectors, or photovoltaic and photoconductive detectors, require cooling solutions for high sensitivity, and often have high cost and need exotic and/or toxic materials, such as HgCdTe which is needed in long-wave infrared detection. Cooling systems incur complexity, power consumption and cost. The main limitation of uncooled optical detectors of both thermal and quantum types is poor performance in terms of sensitivity as described by specific detectivity. State-of-the-art thermal detectors are typically slower than quantum detectors. Thermoelectric transduction provides the benefits of increased sensitivity and low power consumption, compared to resistive detectors requiring active power. Thermoelectric transduction doesn't require external power, since it inherently generates a voltage. Furthermore, since electric current is not needed in signal transduction in the case of thermoelectric elements, there are less noise sources, which results in higher signal-to-noise ratio (that is, increased sensitivity).

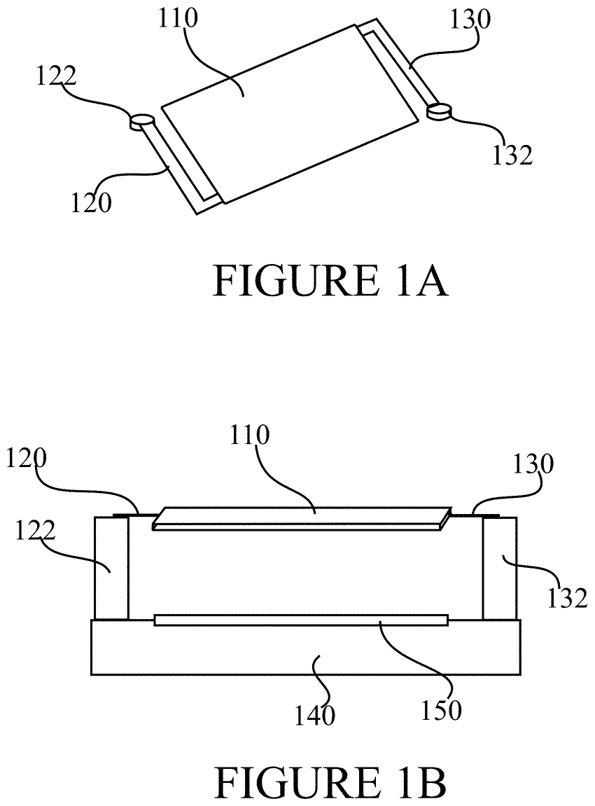

FIG. 1A illustrates an example detector in accordance with at least some embodiments of the present invention. The detector comprises an optically absorbing membrane 110, which will hereafter be referred to as membrane 110 for the sake of brevity. Membrane 110 warms up as a response to incident electromagnetic radiation which it absorbs. n-type semiconductor element 120 connects membrane 110 to stub 122. p-type semiconductor element 130 connects membrane 110 to stub 132. Stubs 122, 132 may be disposed on a substrate, which is not illustrated in FIG. 1A. The substrate may define a cavity under membrane 110, as will be disclosed herein below. The detector may have more than one pair of semiconductor element 120, 130 legs, in which case the structure may be sturdier. Membrane 110 may be thermally isolated by placing it in vacuum.

A thermoelectric transducer consists of two dissimilar thermoelectric materials joined together by a contacting element. The dissimilar thermoelectric materials comprise an n-type semiconductor with negative charge carriers, and a p-type semiconductor with positive charge carriers. In FIG. 1A, the thermoelectric transducer is thus comprised of semiconductor elements 120 and 130. Membrane 110 is arranged to act as a contacting element between n-type and p-type thermoelectric elements 120, 130 of the thermoelectric transducer.

FIG. 1B illustrates an example detector in accordance with at least some embodiments of the present invention. This figure presents a different view of the detector, which comprises the same parts as FIG. 1A, like numbering denoting like structure. The stubs 122, 132 are here seen disposed on substrate 140, which may comprise a suitable material. For example, substrate 140 may comprise a silicon wafer. Stubs 122, 132 may be constructed of an oxide material, such as silicon oxide, for example. The detector of FIG. 1B further comprises a reflector 150, which is arranged to reflect back electromagnetic radiation which has passed through membrane 110 without being absorbed by the membrane. The presence of the reflector thus increases the sensitivity of the detector, since a larger fraction of incident radiation is absorbed by membrane 110. In effect, the radiation is given two opportunities to be absorbed, one before and another after reflection from reflector 150. In effect, an optical cavity is formed between membrane 110 and reflector 150. Reflector 150 may be comprised of metals, semi-metals, highly conductive semiconductors, dielectrics or poorly conducting semiconductors for a distributed Bragg mirror, for example. Alternatively, an N+ (highly/degenerately N doped) or P+ (highly/degenerately N doped) doped semiconductor mirror may be used, with a fully-doped substrate 140, a surface-doped substrate 140 (using implantation or diffusion, for example), or a deposited and doped layer. In some embodiments, substrate 140 itself acts as a reflector, for example where substrate 140 is conducting, such as where it is a highly doped silicon or other semiconductor, or a metallic substrate.

Stubs 122, 132 may provide electrical connections between the thermoelectric transducer 120, 130 and readout electronics configured to process a signal from the detector. For example, these electrical connections may be built using wire bonding using metallic bonding pads, flip-chip bonding or wafer bonding techniques. As a further alternative, substrate 140 may comprise a CMOS circuit. Further, the detector may be interfaced with other optical devices, such as microspectrometer films (e.g. Fabry-Pérot interferometers). Readout electronics are not illustrated in FIG. 1B for the sake of clarity. The stubs may be of an oxide material, which may be a remnant of a sacrificial layer etched during manufacture of the detector. For example, tetraethylorthosilicate, TEOS, silicon oxide, plasma-enhanced chemical vapour deposition, CVD, silicon oxide or low-pressure CVD low temperature oxide, LTO, silicon oxide.

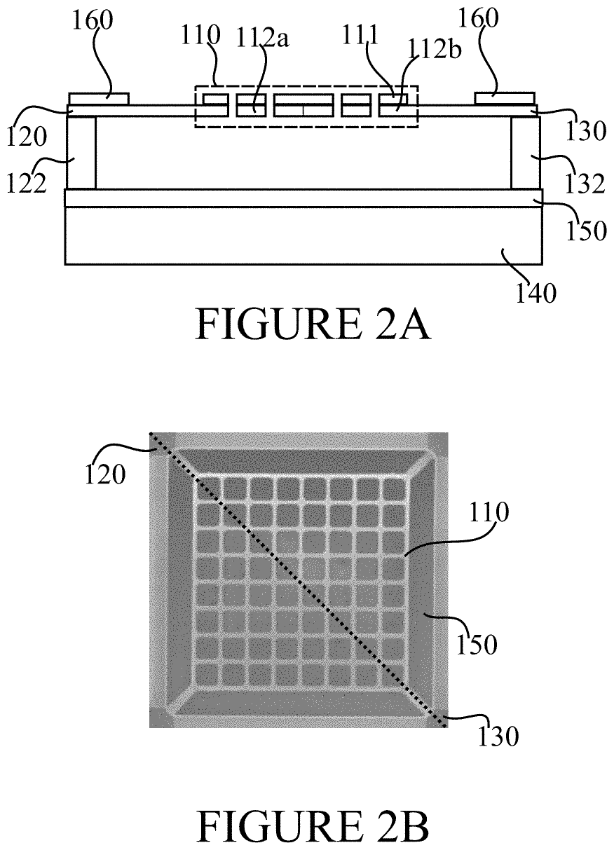

FIG. 2A illustrates an example detector in accordance with at least some embodiments of the present invention. Like numbering denotes like structure as in FIGS. 1A and 1B. Frame 160 is provided to provide stress tuning, such that thermoelectric materials with a wider range of stress characteristics to be used. Without frame 160, thermoelectric materials used in semiconductor elements 120 and 130 may be made of low or moderate tensile stress for suitable suspension of membrane 110. Frame 160 may be placed on top of semiconductor elements 120, 130 as illustrated in FIG. 2A, or it may additionally or alternatively be placed between semiconductor elements 120, 130 and stubs 122, 132, respectively. The frame may be comprised of one of the following materials, for example: silicon nitride (SiNx) and aluminium oxide (Al₂O₃). These materials may be deposited using plasma-enhanced CVD, low-pressure CVD, sputtering, and/or atomic layer deposition (ALD) techniques for example. As described above, in some embodiments frame 160 is absent.

The optically absorbing membrane 110 is illustrated in FIG. 2A as being comprised of a thermoelectric transducer layer 112a, 112b and an optically absorbing layer 111. Physically, thermoelectric transducer layer 112a, 112b and semiconductor elements 120, 130 may be of a same fabricated layer structure. In detail, semiconductor element 120 and thermoelectric transducer layer 112a, which faces thermoelectric element 120, may be of a same semiconductor layer. Semiconductor element 130 and thermoelectric transducer layer 112b, which faces thermoelectric element 130, may be of a same semiconductor layer. In terms of manufacture, optically absorbing layer 111 may be deposited on thermoelectric transducer layer 112a, 112b. In other words, the deposition of optically absorbing layer 111 defines thermoelectric transducer layer 112a, 112b as that part of thermoelectric elements 120, 130 which is overlaid by optically absorbing layer 111. In other embodiments, the optically absorbing layer 111 may be underneath the thermoelectric transducer layer 112a, 112b, that is, on the side of the cavity between membrane 110 and substrate 140. Gaps in membrane 110 schematically indicate the patterning of the membrane, which is an optional feature. Patterning is illustrated more in FIG. 2B, discussed below. The sizes of thermoelectric transducer layers 112a, 112b may be equal or unequal. Where the sizes are unequal, the sizes may be selected such that an overall contact and/or total resistance of the thermoelectric transducer is minimized, in dependence of the specific thermoelectric and absorber materials used. Geometries of thermoelectric elements 120, 130 may be chosen, for example, as in A. Varpula et al., Appl. Phys. Lett. 110, 262101 (2017) or in Thermoelectrics handbook : macro to nano, edited by D. M. Rowe, Taylor & Francis, 2006 and H. Julian Goldsmid, Springer series in materials science 121: Introduction to Thermoelectricity, Springer, 2010.

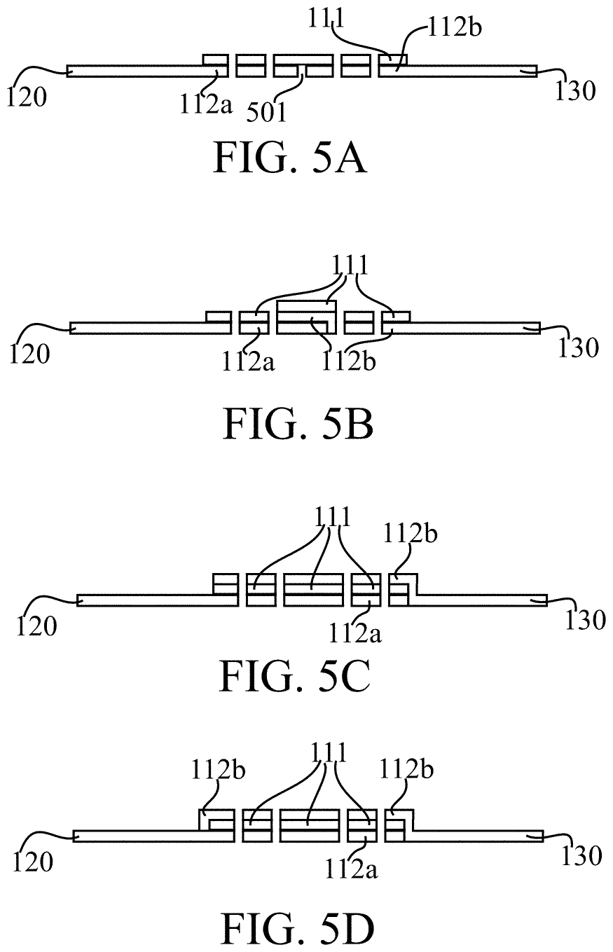

In yet further embodiments, there may be two optically absorbing layers, one on either side of thermoelectric transducer layer 112a, 112b. In other words, the optically absorbing membrane may comprise two optically absorbing layers and the thermoelectric transducer layer, the optically absorbing layers being disposed on either side of the thermoelectric transducer layer. On the other hand, in some embodiments the optically absorbing membrane 110 comprises one and only one optically absorbing layer 111 and exactly one thermoelectric transducer layer 112, the optically absorbing layer 111 being disposed on one and only one side of the thermoelectric transducer layer 112. Specific examples of various membrane embodiments will be discussed in more detail in connection with FIGS. 5A-5D.

Where two optically absorbing layers are present in optically absorbing membrane 110, they may be of the same material , or of different materials. The optically absorbing membrane 110 may have a thickness of less than 800 nanometres, less than 200 nanometres, less than 180 nanometres, less than 160 nanometres, less than 100 nanometres, less than 60 nanometres or less than 20 nanometres, for example. As disclosed above, a thin membrane has low heat capacity, Further, membrane phonon thermal conductivity of in-membrane materials decreases when the thickness is reduced to the nanoscale.

Optically absorbing layers, such as optically absorbing layer 111, may be comprised of metals, semimetals or highly doped semiconductors. Examples include TiW (titanium-tungsten), Ti (titanium), W (tungsten), TiN (titanium nitride), NbN (niobium nitride), MoN (molybdenum nitride), Mo (molybdenum), thin Al , a-Si (amorphous silicon), Al:ZnO (aluminium-doped zinc oxide), highly-doped single and poly crystalline silicon and doped SrTiO₃ (strontium titanate). A further example of the absorber material is infrared absorbing insulators, such as silicon nitride or aluminium oxide. These materials absorb well in a band of infra-red. In the absorbing layers, the conductivity of the material may be selected such that it enables impedance matching to the vacuum impedance with a low thermal mass, that is, the resistance should not optimally be too high, but high enough for good absorptance. For plasmonic absorbers, the permittivity of the selected material , and pattern feature sizes, may beneficially be matched to the desired wavelength. Concerning electrical requirements, the selected absorbing layer 111 material beneficially has low contact resistance with the materials of semiconductor elements 120 and 130 (and thus with thermoelectric transducer layer 112a, 112b). This contact resistance should be much lower than the total resistance of the thermoelectric legs 120, 130, as otherwise performance of the detector is reduced by the contact resistance.

The thermoelectric materials used for thermoelectric elements 120, 130 and thermoelectric transducer layer 112a, 112bmay have a thickness, when applied in the detector, of less than 200 nm. The one is an N-type thermoelectric material and the other is a P-type thermoelectric material. Suitable materials include highly doped N(P)-type silicon, polysilicon and other semiconductors. Doping may be performed with ion implantation, diffusion or other suitable methods. Beneficially, the thermoelectric materials have a high thermoelectric figure of merit, ZT (see e.g. A. Varpula et al., Appl. Phys. Lett. 110, 262101 (2017) for a definition of ZT). For maximal sensitivity of the optical detector the effective thermoelectric figure of merit, the effective ZT, of the device should be maximized. As to mechanical requirements of the thermoelectric materials of elements 120, 130 and thermoelectric transducer layer 112a, 112b, they should have low or moderate tensile stress for suitable suspension of the absorber. Less suitable stress conditions can be handled by benefiting from a frame 160 to tune the stresses in the thermoelectric material.

Examples of suitable thermoelectric materials include Bi₂Te₃ (bismuth telluride), Bi₂Se₃ (bismuth selenide), HgCdTe (mercury cadmium telluride), ZnO₂ (zinc peroxide), SrTiO₃ (strontium titanate), silicon nanowires, thin single-crystalline silicon, thin polysilicon, Bi₂Te₃ (bismuth telluride) and Sb₂Te₃ (antimony telluride).

Optionally, a passivation layer, which is not illustrated in FIG. 2A, may be disposed as a topmost layer on top of membrane 110, elements 120, 130 and frame 160 (when frame 160 is present), to enclose the other layers. The passivation layer may be comprised of Al₂O₃ or SiNx, for example. These materials may be deposited using plasma-enhanced CVD, low-pressure CVD, sputtering, and atomic layer deposition (ALD) techniques for example. The role of the passivation layer is to protect absorbing materials, if needed. The absorbing material sides may be protected by patterning the passivation layer away from the absorber edges, by spacer patterning techniques or they can be left unprotected by patterning the passivation layer and the thermoelectric and absorber materials simultaneously. In some embodiments, one of the thermoelectric materials is used as a passivation layer for the absorbing layer of the optically absorbing membrane.

FIG. 2B illustrates an example detector with patterned membrane in accordance with at least some embodiments of the present invention. The cross section of FIG. 2A is obtained diagonally along the dotted line. As can be seen from FIG. 2B, the optically absorbing membrane 110 is patterned, in detail , patterned with a plurality of holes which perforate the membrane. The holes may be created by etching, such as wet etching or plasma etching, for example. The patterning of the membrane provides the benefit that the membrane is thereby made lighter, which reduces its heat capacity and consequently causes it to heat up faster as a response to incoming electromagnetic radiation. Patterning allows also tuning of the effective sheet resistance of the patterned absorber membrane for optical impedance matching of the absorber (in the case of resistive impedance matched absorber), or tuning of the optical properties of the absorber (in the case of plasmonic absorber). The response time of the detector may thus be improved. The holes may be designed to be smaller than a wavelength of radiation the detector is intended to detect, wherefore absorbance is not adversely affected.

When the wavelength the detector is intended to detect is known, the cavity may also be dimensioned accordingly, such for resistive absorbers that the height of the cavity is a quarter of a center wavelength the thermal detector is arranged to detect. For plasmonic absorbers, the cavity may be different from the quarter of the center wavelength.

In general , there may be provided a detector comprising an optically absorbing membrane 110 suspended over a cavity between the membrane 110 and a substrate 140, and a thermoelectric transducer 120, 130 attaching the optically absorbing membrane 110 over the cavity, wherein the optically absorbing membrane 110 forms a contacting element between n-type 120 and p-type 130 thermoelectric materials of the thermoelectric transducer 120, 130. Membrane 110 may be patterned, for example by perforating it with a plurality of holes. When membrane 110 is patterned, both thermoelectric transducer layer 112 and optically absorbing layer 111 may have the same pattern, such that holes of the pattern, for example, extend through the entire membrane 110.

By being attached over the cavity by the thermoelectric transducer it may be meant, that the legs 120, 130 connecting membrane 110 with the rest of the detector (e.g. stubs 122, 132) do not comprise non-thermoelectric materials. The legs may be connected with or between further structures, such as stubs 122, 132 and frame 160, but the legs themselves may be comprised solely of the thermoelectric materials.

The detector may comprise a back reflector attached in an inside edge of the cavity, arranged to reflect an optical signal not absorbed by the membrane back toward the membrane 110. Thus membrane 110 may have two chances to absorb energy from the optical signal.

The detector may be only passively cooled, by which it is meant the detector does not have an active cooling mechanism. In other words, the detector may be uncooled. Where the detector is actively cooled, it may be cooled using a Peltier chip, for example. An uncooled detector provides, in general , the benefit of slightly better sensitivity.

The detector may comprise a frame 160 either on top of the thermoelectric transducer 120, 130 or between the thermoelectric transducer 120, 130 and stubs 122, 132 defining a height of the cavity. As discussed above, presence of the frame 160 enables using a broader range of thermoelectric materials to build the thermoelectric transducer 120, 130 and the thermoelectric transducer layer 112.

The optically absorbing membrane 110 may be a resistive impedance matched absorber or a plasmonic absorber. Where the membrane is a plasmonic absorber, it may be a broad-band absorber, for example. For plasmonic absorbers the absorbing material permittivity and feature sizes of the pattern may be matched to the wavelength that it is desired to detect with the detector. Where the optically absorbing membrane is a resistive impedance matched absorber, the height of the cavity may be a quarter of a wavelength the detector is arranged to detect.

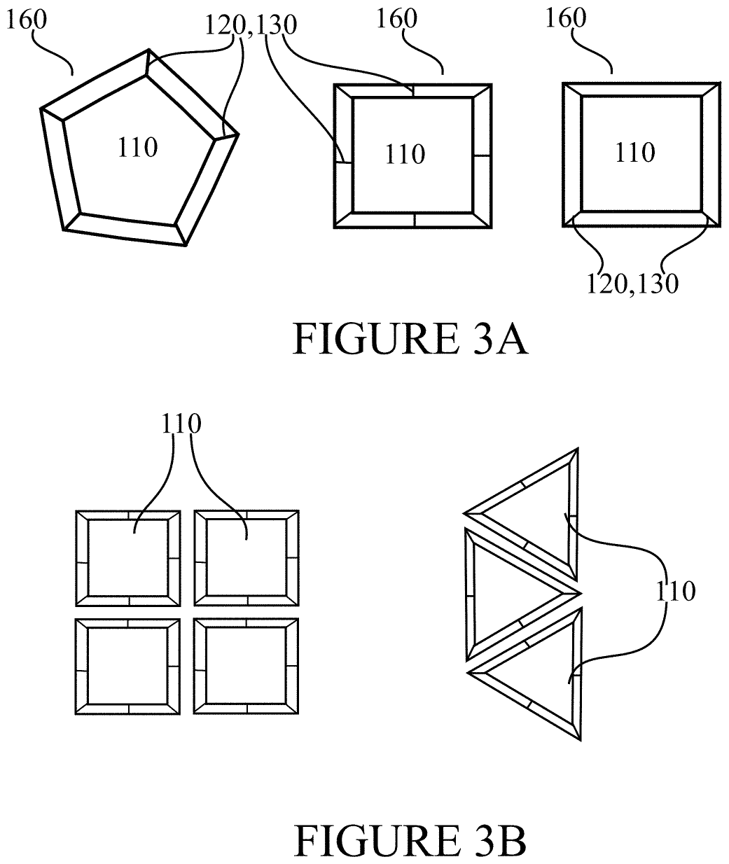

FIG. 3A illustrates examples of device configurations. Like numbering here, too, denotes like structure as in preceding figures. In these examples, the absorber is pentagonal , on the left, and square in the middle and on the right. As can be seen from the figure, the thermoelectric transducer 120, 130 may be arranged to suspend membrane 110 in various ways. A frame, not illustrated in FIG. 3A, may be present, as discussed above.

FIG. 3B illustrates examples of device configurations. These configurations relate to multi-detector arrays. Such arrays may be constructed of detectors of differing shapes. For example, on the left is an array of square detectors, and on the right is an array of triangular detectors constructed as disclosed herein. Detector arrays may be used in imaging applications where the detector array forms a multi-pixel image sensor. Detector arrays may also be used in spectroscopic applications, such that the detectors comprised in an array are tuned to respond to incoming electromagnetic radiation of different wavelengths. The absorbers 110 will beneficially cover as much of the total detector area as possible. A frame, not illustrated in FIG. 3B, may be present, as discussed above.

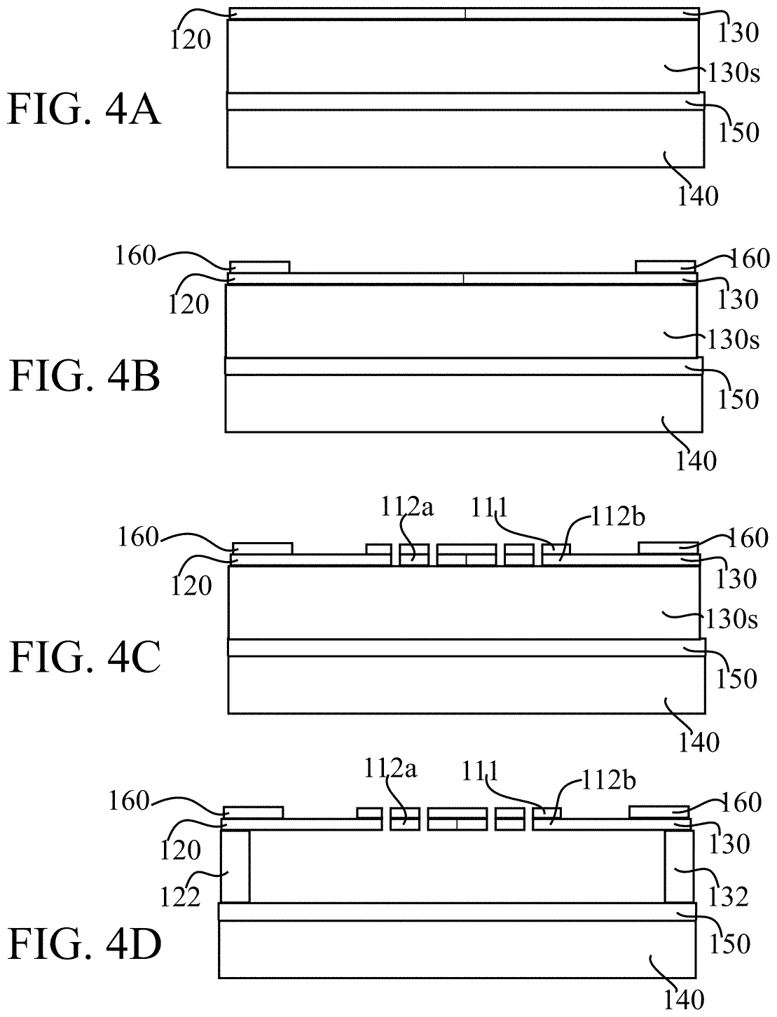

FIG. 4 illustrates phases of a manufacturing method. In FIG. 4A, the process has begun with a silicon wafer 140, which may be doped to generate the reflector 150. As an alternative, a metallic layer may be placed on substrate 140 to construct reflector 150. Subsequently, a sacrificial silicon oxide layer 130s is deposited on reflector 150 (or substrate 140, where substrate 140 is itself reflective). Then poly silicon deposition, doping and patterning to generate the thermoelectric legs 120, 130 (visible in FIGS. 1B, 2B) is performed to arrive at the situation depicted in FIG. 4A, with the thermoelectric elements 120, 130 present on the sacrificial layer 130s.

Processing then advances to the phase illustrated in FIG. 4B. To arrive at the situation of FIG. 4B, frame 160 material is deposited onto the thermoelectric materials to construct frame 160. Patterning may be employed in the construction of frame 160. As disclosed herein above, the frame may be constructed of Al₂O₃ or silicon nitride, for example.

Processing then advances to the phase illustrated in FIG. 4C. To arrive at the situation of FIG. 4C, the absorbing material is deposited on the thermoelectric materials to form the absorbing membrane. The part of the thermoelectric elements 120, 130 overlaid by the absorbing material becomes the thermoelectric transducer layer 112a, 112b, while the absorbing material itself constitutes the optically absorbing layer 111. These two layers together are the optically absorbing membrane 110. The membrane is in this embodiment patterned, as disclosed herein above. The patterning may comprise perforating, for example.

Advancing then finally to the phase illustrated in FIG. 4D, the sacrificial layer is removed to construct the cavity between the optically absorbing membrane 110 and reflector 150 (or substrate 140, where substrate 140 is itself reflective), for example by releasing the silicon via hydrofluoric, HF, vapour. Alternatively, the release may take place as wet etching using a HF solution or buffered HF solution. As remnants of the sacrificial layer, stubs 122 and 132 remain, for example to provide electrical connections between the thermoelectric transducer and readout electronics.

FIGS. 5A-5D illustrates variant optically absorbing membrane 110 structures. In these figures, only the thermoelectric and absorbing layers are illustrated for the sake of clarity and the stubs, the cavity, the substrate and optional frame are not.

FIG. 5A illustrates a membrane structure which differs from the membrane 110 of FIG. 2A in that there is a gap 501 between the thermoelectric elements 120, 130 of the thermoelectric transducer layer 112a, 112b. The gap may be manufactured in place before the absorbing material is deposited. Thus in this case, the optically absorbing layer 111 provides the only electrical connection between the thermoelectric elements 120 and 130. In practice, absorbing layer 111 may extend into gap 501.

The arrangement of FIG. 5A may be expressed as an arrangement, where the optically absorbing membrane forms a contacting element between n-type and p-type thermoelectric elements of the thermoelectric transducer, wherein the optically absorbing membrane comprises an optically absorbing layer overlaid on a thermoelectric transducer layer, there being a gap in the thermoelectric transducer layer separating the n-type thermoelectric element from the p-type thermoelectric element. The membrane may be patterned.

FIG. 5B illustrates a membrane structure which differs from membrane 110 of FIG. 2A in that one of the thermoelectric materials party overlays the other. In detail , in one part of the membrane there is a three-layer section where the thermoelectric elements overlay each other, and are further overlaid by at least one absorbing layer 111. In effect, there are two thermoelectric transducer layers, one corresponding to each thermoelectric material type. These are illustrated as layer 112a and layer 112b.

The arrangement of FIG. 5B may be expressed as an arrangement, where the optically absorbing membrane forms a contacting element between n-type and p-type thermoelectric elements of the thermoelectric transducer, wherein the optically absorbing membrane comprises a section where the n-type and p-type thermoelectric elements overlay each other, and are overlaid by an optically absorbing layer. Thus in this section three layers overlay each other. The specific order in which the layers overlay each other may differ from that illustrated.

FIG. 5C illustrates a membrane structure which differs from the membrane of FIG. 5B in that the overlap between the thermoelectric layers is more extensive. A further difference is that the thermoelectric materials of thermoelectric transducer layer 112 are arranged on either side of absorbing layer 111. In effect, there are two thermoelectric transducer layers, one corresponding to each thermoelectric material type. These are illustrated as layer 112a and layer 112b in FIG. 5C.

The arrangement of FIG. 5C may be expressed as an arrangement, where the optically absorbing membrane forms a contacting element between n-type and p-type thermoelectric elements of the thermoelectric transducer, wherein the optically absorbing membrane comprises a section where the n-type and p-type thermoelectric elements are disposed on either side of an optically absorbing layer for the entire length of the optically absorbing layer. Thus three layers overlay each other.

FIG. 5D illustrates a membrane structure which differs from the membrane of FIG. 5C in that the thermoelectric transducer layer 112b corresponding to thermoelectric element 130 encloses the optically absorbing layer 111 to make a direct connection with the thermoelectric transducer layer 112a corresponding to thermoelectric element 120. In effect, there are two thermoelectric transducer layers 112, one corresponding to each thermoelectric material type. These are illustrated as layer 112a and layer 112b.

The arrangement of FIG. 5D may be expressed as an arrangement, where the optically absorbing membrane forms a contacting element between n-type and p-type thermoelectric elements of the thermoelectric transducer, wherein the optically absorbing membrane comprises a section where the n-type and p-type thermoelectric elements are disposed on either side of an optically absorbing layer for the entire length of the optically absorbing layer, and wherein the n-type and p-type thermoelectric elements enclose the optically absorbing member by directly connecting to each other. Thus three layers overlay each other. A benefit of this arrangement is that passivation of the absorbing layer can be achieved using a thermoelectric material , without using a separate passivation layer. Alternatively, a separate passivation layer may coat the optically absorbing membrane of one or more of FIGS. 5A-5D.

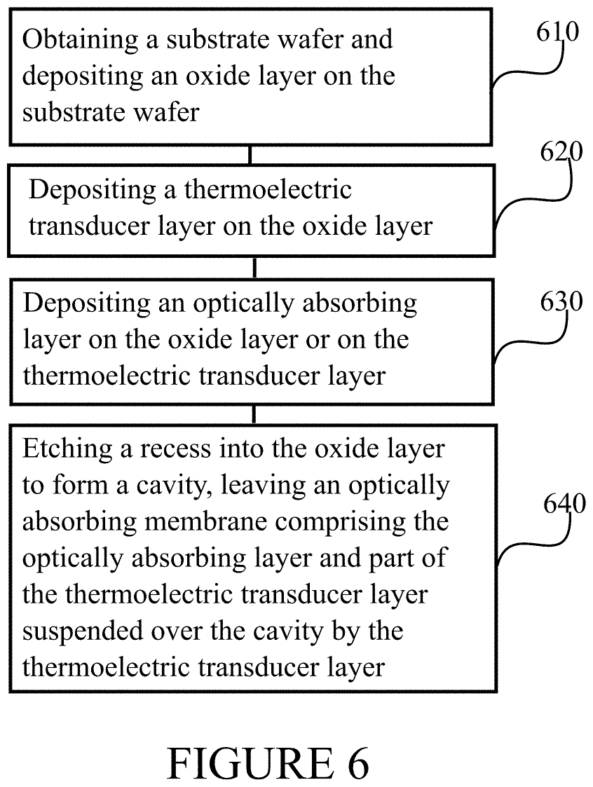

FIG. 6 is a flow graph of a method in accordance with at least some embodiments of the present invention. Phase 610 comprises obtaining a substrate wafer and depositing an oxide layer on the substrate wafer. Phase 620 comprises depositing a thermoelectric transducer layer on the oxide layer. Phase 630 comprises depositing an optically absorbing layer on the oxide layer or on the thermoelectric transducer layer. Finally, phase 640 comprises etching a recess into the oxide layer to form a cavity, leaving an optically absorbing membrane comprising the optically absorbing layer and part of the thermoelectric transducer layer suspended over the cavity by the thermoelectric transducer layer. The thermoelectric transducer layer may comprise two layers, one corresponding to an n-type thermoelectric element and one corresponding to a p-type thermoelectric element. The oxide may comprise silicon oxide, for example.

The following combinations of materials may be employed in construction of the detector. A single combination of materials is disclosed on a single row:

| | | | thermoelectric | thermoelectric |
|---|---|---|---|---|
| Oxide | Frame | Absorber | material 1 | material 2 |
| SiO₂ | Al₂O₃ | TiN | Si | |
| SiO₂ | Al₂O₃ | TiW | Si | |
| SiO₂ | Al₂O₃ | Ti | Si | |
| SiO₂ | Al₂O₃ | Al:Zno | Si | |
| SiO₂ | Al₂O₃ | Al | Si | |
| SiO₂ | Al₂O₃ | TiN | Bi₂Te₃ | |
| SiO₂ | Al₂O₃ | TiW | Bi₂Te₃ | |
| SiO₂ | Al₂O₃ | Ti | Bi₂Te₃ | |
| SiO₂ | Al₂O₃ | Al:Zno | Bi₂Te₃ | |
| SiO₂ | Al₂O₃ | Al | Bi₂Te₃ | |
| SiO₂ | Al₂O₃ | TiN | Bi₂Te₃ | Sb₂Te₃ |
| SiO₂ | Al₂O₃ | TiW | Bi₂Te₃ | Sb₂Te₃ |
| SiO₂ | Al₂O₃ | Ti | Bi₂Te₃ | Sb₂Te₃ |
| SiO₂ | Al₂O₃ | Al:Zno | Bi₂Te₃ | Sb₂Te₃ |
| SiO₂ | Al₂O₃ | Al | Bi₂Te₃ | Sb₂Te₃ |
| SiO₂ | Al₂O₃ | TiN | SrTiO₃ | Si |
| SiO₂ | Al₂O₃ | TiW | SrTiO₃ | Si |
| SiO₂ | Al₂O₃ | Ti | SrTiO₃ | Si |
| SiO₂ | Al₂O₃ | Al:Zno | SrTiO₃ | Si |
| SiO₂ | Al₂O₃ | Al | SrTiO₃ | Si |
| SiO₂ | (none) | TiN | Si | |
| SiO₂ | (none) | TiW | Si | |
| SiO₂ | (none) | Ti | Si | |
| SiO₂ | (none) | Al:Zno | Si | |
| SiO₂ | (none) | Al | Si | |
| SiO₂ | (none) | TiN | Bi₂Te₃ | |
| SiO₂ | (none) | TiW | Bi₂Te₃ | |
| SiO₂ | (none) | Ti | Bi₂Te₃ | |
| SiO₂ | (none) | Al:Zno | Bi₂Te₃ | |
| SiO₂ | (none) | Al | Bi₂Te₃ | |
| SiO₂ | (none) | TiN | Bi₂Te₃ | Sb₂Te₃ |
| SiO₂ | (none) | TiW | Bi₂Te₃ | Sb₂Te₃ |
| SiO₂ | (none) | Ti | Bi₂Te₃ | Sb₂Te₃ |
| SiO₂ | (none) | Al:Zno | Bi₂Te₃ | Sb₂Te₃ |
| SiO₂ | (none) | Al | Bi₂Te₃ | Sb₂Te₃ |
| SiO₂ | (none) | TiN | SrTiO₃ | Si |
| SiO₂ | (none) | TiW | SrTiO₃ | Si |
| SiO₂ | (none) | Ti | SrTiO₃ | Si |
| SiO₂ | (none) | Al:Zno | SrTiO₃ | Si |
| SiO₂ | (none) | Al | SrTiO₃ | Si |

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in using and manufacturing detectors. Examples of potential detector applications include infrared imaging, infrared chemical analysis based on absorption spectroscopy, for example, and temperature measurements. These devices can also be used as calorimetric sensors.

### ACRONYMS LIST

ALD atomic layer deposition

CVD chemical vapour deposition

LPCVD low-pressure CVD

LTO low temperature oxide

PECVD plasma-enhanced CVD

### REFERENCE SIGNS LIST

| | |
|---|---|
| 110 | optically absorbing membrane (“membrane”) |
| 111 | optically absorbing layer |
| 112a, 112b | thermoelectric transducer layer |
| 120, 130 | thermoelectric element |
| 122, 132 | stubs |
| 140 | substrate |
| 150 | reflector |
| 160 | frame |
| 501 | gap |
| 610-640 | phases of the process of FIG. 6 |

1. A detector comprising:
an optically absorbing membrane suspended over a cavity between the membrane and a substrate, the substrate comprised in the detector, and
a thermoelectric transducer attaching the optically absorbing membrane over the cavity, wherein the optically absorbing membrane forms a contacting element between n-type and p-type thermoelectric elements of the thermoelectric transducer, wherein the attachment of the optically absorbing membrane over the cavity by the thermoelectric transducer is by legs which do not comprise non-thermoelectric material.

2. (canceled)

3. The detector according to claim 1, wherein the membrane has a thickness of less than 800 nanometres, less than 200 nanometres, less than 180 nanometres, less than 160 nanometres, less than 100 nanometres, less than 60 nanometres or less than 20 nanometres.

4. The detector according to claim 1, wherein the detector further comprises a back reflector attached in an inside edge of the cavity, arranged to reflect an optical signal not absorbed by the membrane back toward the membrane.

5. The detector according to claim 1, wherein the detector is only passively cooled.

6. The detector according to claim 1, further comprising a frame either on top of the thermoelectric transducer or between the thermoelectric transducer and stubs defining a height of the cavity.

7. The detector according to claim 6, wherein the frame is composed of aluminium oxide.

8. The detector according to claim 1, wherein the thermoelectric transducer is comprised in part of silicon.

9. The detector according to claim 1, wherein the thermoelectric transducer is comprised in part of bismuth telluride.

10. The detector according to claim 1, wherein the thermoelectric transducer is comprised in part of antimony telluride.

11. The detector according to claim 1, wherein the optically absorbing membrane is comprised of titanium nitride.

12. The detector according to claim 1, wherein the optically absorbing membrane is comprised of titanium-tungsten.

13. The detector according to claim 1, wherein the optically absorbing membrane is comprised of titanium.

14. The detector according to claim 1, wherein the optically absorbing membrane is comprised of aluminium-doped zinc oxide.

15. The detector according to claim 1, wherein the optically absorbing membrane is comprised of aluminium.

16. The detector according to claim 6, wherein the stubs comprise electrical connections between the thermoelectric transducer and readout electronics configured to process a signal from the detector.

17. The detector according to claim 16, wherein the stubs are composed of silicon oxide.

18. The detector according to claim 1, wherein the optically absorbing membrane is a resistive impedance matched absorber or a plasmonic absorber.

19. The detector according to claim 18, wherein the optically absorbing membrane is the resistive impedance matched absorber, and wherein the height of the cavity is a quarter of a wavelength the detector is arranged to detect.

20. The detector according to claim 1, wherein the substrate comprises a silicon layer.

21. The detector according to claim 1, wherein the optically absorbing membrane is patterned with a pattern which includes puncturing the membrane with a plurality of holes.

22. The detector according to claim 1, wherein the optically absorbing membrane comprises two optically absorbing layers and a thermoelectric transducer layer, the optically absorbing layers being disposed on either side of the thermoelectric transducer layer.

23. The detector according to claim 1, wherein the optically absorbing membrane comprises one and only one optically absorbing layer and a thermoelectric transducer layer, the optically absorbing layer being disposed on one and only one side of the thermoelectric transducer layer.

24. The detector according to claim 1, wherein one and only one of the following applies:
the optically absorbing membrane comprises an optically absorbing layer overlaid on a thermoelectric transducer layer, there being a gap in the thermoelectric transducer layer separating the n-type thermoelectric element from the p-type thermoelectric element;
the optically absorbing membrane comprises a section where the n-type and p-type thermoelectric elements overlay each other, and are overlaid by an optically absorbing layer;
the optically absorbing membrane comprises a section where the n-type and p-type thermoelectric elements are disposed on either side of an optically absorbing layer for the entire length of the optically absorbing layer, and
the optically absorbing membrane comprises a section where the n-type and p-type thermoelectric elements are disposed on either side of an optically absorbing layer for the entire length of the optically absorbing layer, and wherein the n-type and p-type thermoelectric elements enclose the optically absorbing member by directly connecting to each other.

25. A method of manufacturing a detector, comprising:
obtaining a substrate wafer and depositing an oxide layer on the substrate wafer;
depositing a thermoelectric transducer layer on the oxide layer;
depositing an optically absorbing layer on the oxide layer or on the thermoelectric transducer layer, and
etching a recess into the oxide layer to form a cavity, leaving an optically absorbing membrane comprising the optically absorbing layer and part of the thermoelectric transducer layer suspended over the cavity by the thermoelectric transducer layer, wherein the attachment of the optically absorbing membrane over the cavity by the thermoelectric transducer is by legs which do not comprise non-thermoelectric material.

26. (canceled)
